(19) United States
(12) Patent Application Publication
(10) Pub. No.: US 2016/0073493 A1
(43) Pub. Date: Mar. 10, 2016

(54) STIFFENER RING FOR CIRCUIT BOARD

(71) Applicants: Andrew KW Leung, Markham (CA); Suming Hu, North York (CA); Jianguo Li, Scarborough (CA)

(72) Inventors: Andrew KW Leung, Markham (CA); Suming Hu, North York (CA); Jianguo Li, Scarborough (CA)

(21) Appl. No.: 14/478,561

(22) Filed: Sep. 5, 2014

(51) Int. Cl. H05K 1/02; H01L 23/32; H05K 1/18

(52) U.S. Cl. CPC H05K 1/0271; H05K 1/18; H01L 23/32; H05K 2201/09136

(57) ABSTRACT

Various stiffener rings and circuit boards are disclosed. In one aspect, an apparatus is provided that includes a stiffener ring that has a first flange to engage a first principal side of a circuit board and a peripheral wall to engage an external peripheral wall of the circuit board.

### BACKGROUND OF THE INVENTION

1. Field of the Invention

This invention relates generally to semiconductor processing, and more particularly to circuit boards with stiffener rings and to methods of making the same.

2. Description of the Related Art

Many current integrated circuits are formed as multiple die on a common silicon wafer. After the basic process steps to form the circuits on the die are complete, the individual die are cut from the wafer. The cut die are then usually mounted to structures, such as circuit boards, or packaged in some form of enclosure.

One frequently-used package consists of a substrate upon which a die is mounted. The upper surface of the substrate includes electrical interconnects. The die is manufactured with a plurality of bond pads. A collection of solder bumps are provided between the bond pads of the die and substrate interconnects to establish ohmic contact. An underfill material is deposited between the die and the substrate to act as a material that prevents damage to the solder bumps due to mismatches in the coefficients of thermal expansion between the die and the substrate, and an adhesive to hold the die. The substrate interconnects include an array of solder pads that are arranged to line up with the die solder bumps. After the die is seated on the substrate, a reflow process is performed to enable the solder bumps of the die to metallurgically link to the solder pads of the substrate. After the die is mounted to the substrate, a lid is attached to the substrate to cover the die. For lidless designs, a heat spreader plate is sometimes placed in thermal contact with the mounted die. Some conventional integrated circuits, such as microprocessors and graphics processors, generate sizeable quantities of heat that must be ferried away to avoid device shutdown or damage. For these devices, the lid serves as both a protective cover and a heat transfer pathway.

One conventional type of substrate consists of a core laminated between upper and lower build-up layers. The core itself usually consists of four plies of glass filled epoxy. The build-up layers, which may number four or more on opposite sides of the core, are formed from some type of resin. Various metallization structures are interspersed in the core and build-up layers in order to provide electrical pathways between pins or pads on the lowermost layer of the substrate and pads that bond with the chip solder bumps.

The core provides a certain stiffness to the substrate. Even with that provided stiffness, conventional substrates still tend to warp due to mismatches in coefficients of thermal expansion for the chip, underfill and substrate. However, there is a need to provide shorter electrical pathways in package substrates in order to lower power supply inductance and improve power fidelity for power transferred through the substrate. The difficult problem is how to reduce the electrical pathways without inducing potentially damaging substrate warping.

One conventional technique for reducing electrical pathways is to use so-called “coreless” substrates. While coreless substrates may provide more favorable electrical characteristics than a comparably sized substrate with a core, their very thinness can lead to greater warpage and greater risk of substrate damage, particularly at the substrate corners. Conventional substrate corners are typically at or very near 90°.

One conventional technique to reduce substrate warpage is the usage of a stiffener frame on the substrate. Conventional stiffener frames are typically flat frames mounted on the substrate with external edges that are co-terminus with the edges of the substrate. Some conventional designs consist of an external frame with internal spoke-like structures that straddle a mounted chip and passive components. These conventional geometries may not overcome substrate warpage.

The present invention is directed to overcoming or reducing the effects of one or more of the foregoing disadvantages.

### SUMMARY OF EMBODIMENTS OF THE INVENTION

In accordance with one aspect of an embodiment of the present invention, a method of manufacturing is provided that includes fabricating a stiffener ring that has a first flange to engage a first principal side of a circuit board and a peripheral wall to engage an external peripheral wall of the circuit board.

In accordance with another aspect of an embodiment of the present invention, an apparatus is provided that includes a stiffener ring that has a first flange to engage a first principal side of a circuit board and a peripheral wall to engage an external peripheral wall of the circuit board.

In accordance with another aspect of an embodiment of the present invention, an apparatus is provided that includes a circuit board that has a first principal side, a second principal side and external peripheral wall. A stiffener ring has a first flange to engage the first principal side and a peripheral wall to engage the external peripheral wall of the circuit board.

### BRIEF DESCRIPTION OF THE DRAWINGS

The foregoing and other advantages of the invention will become apparent upon reading the following detailed description and upon reference to the drawings in which:

FIG. 1 is a partially exploded pictorial view of an exemplary embodiment of a semiconductor chip device that includes a stiffener ring;

FIG. 2 is a sectional view of FIG. 1 taken at section 2-2;

FIG. 3 is a portion of FIG. 2 shown at greater magnification;

FIG. 4 is a partially exploded pictorial view of an alternate exemplary embodiment of a semiconductor chip device that includes a stiffener ring;

FIG. 5 is a sectional view like FIG. 2 but of a portion of FIG. 4;

FIG. 6 is a sectional view like FIG. 5 by depicting an alternate exemplary embodiment of a stiffener ring;

FIG. 7 is a partially exploded pictorial view of an alternate exemplary embodiment of a semiconductor chip device that includes a stiffener ring;

FIG. 8 is a pictorial view of an alternate exemplary embodiment of a stiffener ring;

FIG. 9 is a plan view of an alternate exemplary embodiment of a stiffener ring mounted to a circuit board; and

FIG. 10 is a plan view of an alternate exemplary embodiment of a stiffener ring mounted to a circuit board.

### DETAILED DESCRIPTION OF SPECIFIC EMBODIMENTS

Various embodiments of a semiconductor chip device are disclosed. One example includes a semiconductor chip mounted to a circuit board. A stiffener ring is also mounted to the circuit board. Various arrangements of the stiffener ring include a top flange to engage a top surface and a peripheral wall to engage an external wall of a circuit board. Other arrangements include a bottom flange to engage a lower surface of the circuit board. Single and multi-piece rings are disclosed. Additional details will now be described.

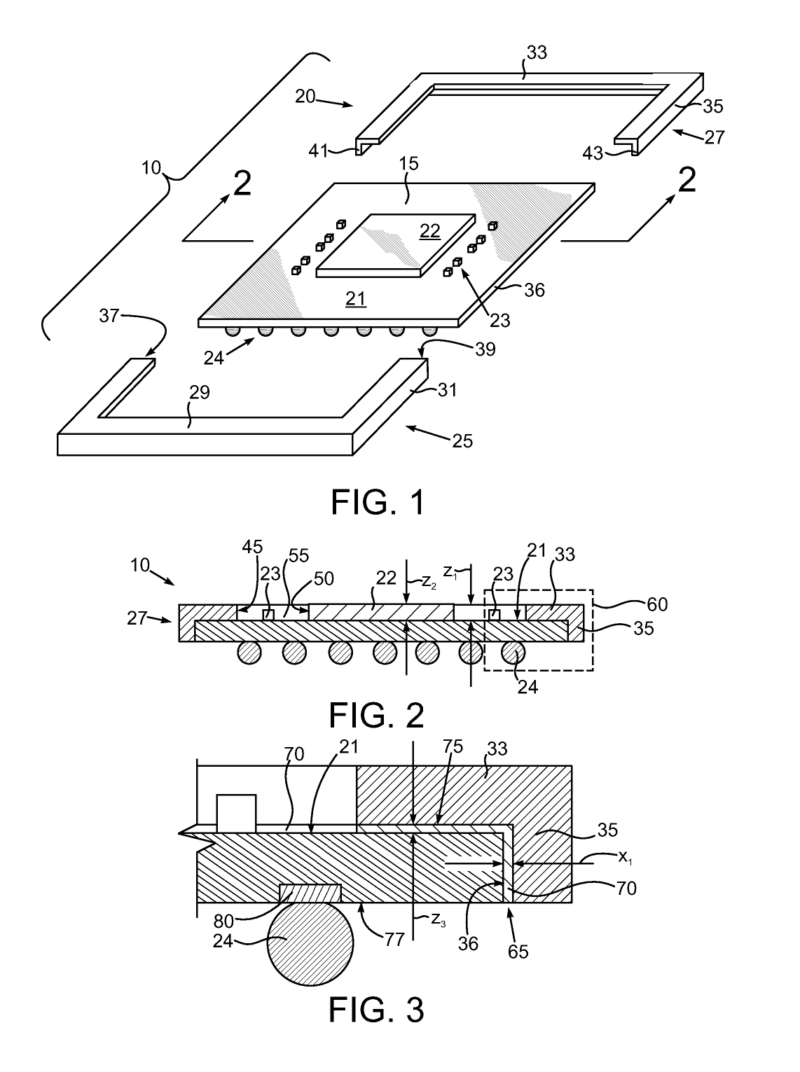

In the drawings described below, reference numerals are generally repeated where identical elements appear in more than one figure. Turning now to the drawings, and in particular to FIG. 1, therein is shown a partially exploded pictorial view of an exemplary embodiment of a semiconductor chip device 10 that includes a circuit board 15 and a stiffener ring 20 to enhance the stiffness of the circuit board 15. A principal side or upper surface 21 of the circuit board 15 may have one or more semiconductor chips 22 and components 23 mounted thereon. To facilitate electrical interface with other circuit boards or devices, the circuit board 15 may be provided with an interconnect arrangement, such as the depicted ball grid array 24. However, other types of interconnects may be used, such as pin grid arrays, land grid arrays or other types. The principal side 21 of the circuit board 15 (and other surfaces if desired) may be populated with the plural components 23, which may be passive components such as capacitors, inductors or resistors or other types of electronic components. Note that the stiffener ring 20 is sized so that components 23 may be easily spatially accommodated.

Still referring to FIG. 1, the circuit board 15 may be a package substrate, circuit card, system board or other type of printed circuit board. Monolithic or buildup structures may be used. If a buildup design is used, the circuit board 15 may consist of a central core upon which one or more build-up layers are formed and below which an additional one or more build-up layers are formed. The core itself may consist of a stack of one or more layers. One example of such an arrangement may be termed a so called “2-2-2” arrangement where a single-layer core is laminated between two sets of two build-up layers. The number of layers in the circuit board 15 can vary from four to sixteen or more, although less than four may be used. So-called “coreless” designs may be used as well. Indeed, coreless or other types of designs may benefit from the stiffness provided by the stiffener ring 20. The layers of the circuit board 15 consist of an insulating material, such as various well-known epoxies or other resins, interspersed with metal interconnects. A multi-layer configuration other than buildup could be used. Optionally, the circuit board 15 may be composed of well-known ceramics or other materials suitable for package substrates or other printed circuit boards.

The semiconductor chip 22 and any alternatives thereof disclosed herein may be any of a myriad of different types of circuit devices used in electronics, such as, for example, microprocessors, graphics processors, combined microprocessor/graphics processors, application specific integrated circuits, memory devices or others, and may be single or multi-core or even stacked with additional dice. The semiconductor chip 22 may be constructed of bulk semiconductor, such as silicon or germanium, or semiconductor on insulator materials, such as silicon-on-insulators materials, or graphene structures. The semiconductor chip(s) 22 may be flip-chip mounted to the circuit board 15 and electrically connected thereto by solder joints, conductive pillars or other structures (not shown). Optionally, wire bonding may be used. The semiconductor chip(s) 22 may be covered with a lid or glob top or have another type of encapsulant (not shown).

In this illustrative embodiment, the stiffener ring 20 may be a two-piece configuration consisting of mating portions 25 and 27. The portions 25 and 27 of this illustrative embodiment and any disclosed alternatives may be identical in size or different as desired. The portion 25 may have an upper flange 29 that is integral with a downwardly projecting peripheral wall 31 while the portion 27 may similarly consist of an upper flange 33 and a downwardly projecting peripheral wall 35. The flanges 29 and 33 are designed to seat on the circuit board 15 and the peripheral walls 31 and 35 are designed to engage an external peripheral wall 36 of the circuit board 15. The portion 25 terminates in a pair of end faces 37 and 39 while the portion 27 terminates in another pair of end faces 41 and 43. The portions 25 and 27 may be sized so that the end faces 37 and 41 and the end faces 39 and 43 physically engage when the stiffener ring 20 is mounted to the circuit board 15 or not as desired. Additional details of the structure and function of the stiffener ring 20 will be described in conjunction with subsequent figures.

Additional details of the semiconductor chip device 10 may be understood by referring now also to FIG. 2, which is a sectional view of FIG. 1 taken at section 2-2. Note that section 2-2 is located such that a portion of the stiffener ring portion 27 is in section. The following discussion of the ring portion will be illustrative of the ring portion 25 as well, albeit in the opposite orientation. The ring portion 27 has an internal peripheral wall 45, which is spaced from an external peripheral wall 50 of the chip 22 to leave a space 55 to accommodate the surface components 23. The stiffener ring portion 27 may have some height z₁ above the surface 21 of the circuit board 15 that is less than, equal to or greater than the height z₂ of the chip above the surface 21 of the circuit board 15. For example, if it is necessary for a heat spreader (not shown) with a large footprint to be mounted on the semiconductor chip 15, then it may be advantageous to fabricate the stiffener ring portion 27 with a height z₁ that is less than the height z₂ of the chip 22.

Note the location of the dashed rectangle 60 in FIG. 2. That portion of FIG. 2 circumscribed by the dashed rectangle 60, which includes the flange 33, the peripheral wall 35 and a portion of the ball grid array 24, will be shown at greater magnification in FIG. 3. Attention is now turned to FIG. 3. The portion 27 may be sized laterally such that when mounted on the circuit board 15, a lateral gap 65 exists between the peripheral wall 35 and the external peripheral wall 36 of the circuit board 15. This gap 65 may be filled with a suitable adhesive 70, which may be a polymer based adhesive, such as various well-known epoxies, b-stage adhesives, or even solders if there are not exposed electrical contacts which might be shorted by such conducting materials present. Indeed, it may be possible to provide the adhesive 70 between the flange 33 of the portion 27 the principal side 21 of the circuit board 15 and thereby establish another gap 75. The gap 65 may have some width x₁, which may be relatively small, perhaps on the order of a fraction of a millimeter and the optional gap 75 may similarly have some dimension z₃ which may be on the order of a fraction of a millimeter. However, the application of the adhesive 70 such that the gap 75 is established is optional in that the flange 33 may be seated directly on the principal side 21 of the circuit board 15 and the adhesive 70 in the gap 65 used exclusively to bond the portion 27 to the circuit board 15. The solder ball 24 projects from the principal or lower side 77 of the circuit board 15 and may be ohmically connected to a ball pad 80, which may be tied electrically to the other components of the circuit board 15 that are not shown for simplicity of illustration. The wrap around nature of the flange 33 and peripheral wall 35 provides a larger engagement surface area for engagement with the circuit board 15 than a conventional stiffener ring, which would engage only the principal side 21 of the circuit board 15.

The ring portions 25 and 27 and any disclosed alternatives may be composed of a variety of materials, such as, for example, aluminum, copper, stainless steel, nickel, alloys of these, such as C2680 or C1100 copper alloys, steels, or the like. Steel-nickel alloys, such as Invar, may provide favorably low thermal expansion. Optionally, well-known plastics may be used. For a given ring portion, such as the portion 27, the flange 33 and peripheral wall 35 may be integral or joined as separate components as desired. The ring portions 25 and 27 may be formed by stamping, forging, casting, molding or machining or some combination of such processes as desired.

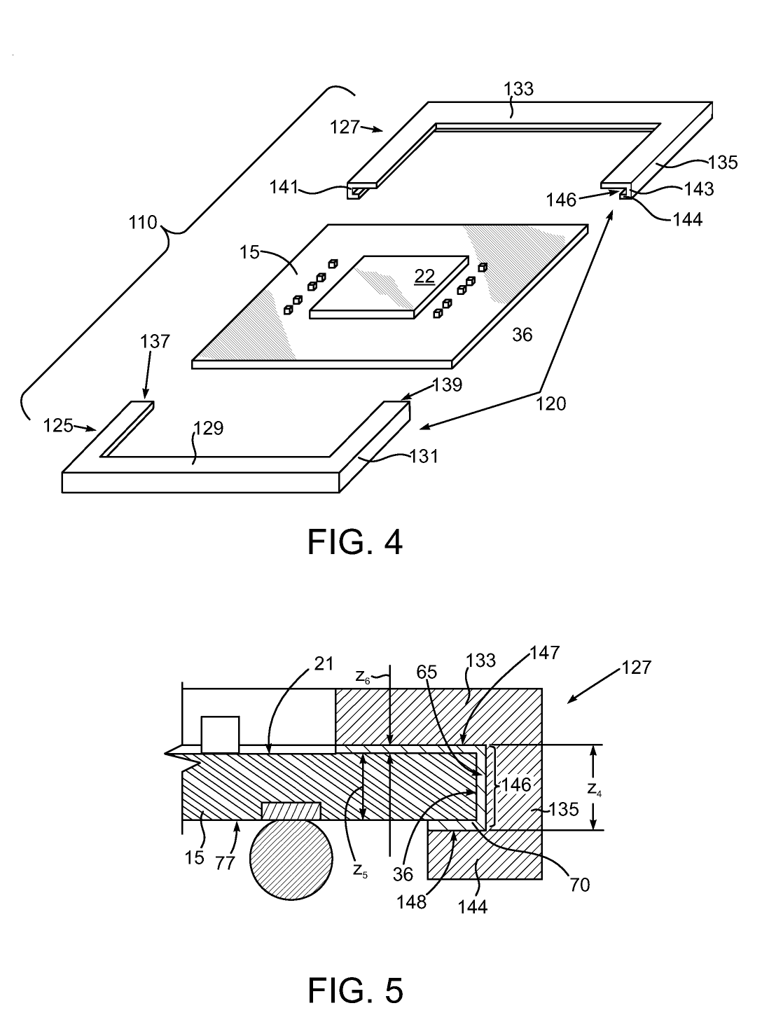

An alternate exemplary embodiment of a semiconductor chip device 110 may be understood by referring now to FIG. 4, which is a partially exploded pictorial view like FIG. 1. Here, the circuit board 15 and semiconductor chip 22 arrangement may be substantially as described above. In this illustrative embodiment, the stiffener ring 120 may consist of cooperating portions 125 and 127. The portion 125 may consist of an upper flange 129 and a peripheral wall 131. The portion 127 may similarly consist of an upper flange 133 and a peripheral wall 135, and the portions 125 and 127 may include end faces 137, 139, 141 and 143 that may or may not engage. However, in this illustrative embodiment, the portion 127 includes a lower flange 144 connected to the peripheral wall 135. The bottom flange 144 and the top flange 133 create a slot 146 that portions of the peripheral wall 36 of the circuit board 15 may slide in and out of Note that the portion 125 has the same type of lower flange and slot, though those features are not visible in FIG. 4.

Additional details of the structure and function of the stiffener ring 120 depicted in FIG. 4 may be understood by referring now to FIG. 5, which is a sectional view like FIG. 3 but in this case of a portion of the stiffener ring portion 127 shown in section. As with the illustrative embodiment depicted in FIGS. 1-3, the portion 127 may have a lateral dimension that leaves the aforementioned gap 65 relative to the peripheral wall 36 of the circuit board 15. In addition, the slot 146 may have some height z₄ that is larger than the thickness z₅ of the circuit board 15 so that the adhesive 70 may optionally be positioned between the surfaces of the flange 133, the peripheral wall 135 and the flange 144 of the portion 127 that oppose surfaces, such as the principal sides 21 and 77 and external peripheral wall 36, of the circuit board 15. Gaps 147 and 148 between the circuit board 15 and the flanges 133 and 144, respectively, may have some thickness z₆ that may or may not be equal and the same as the thickness of the gap 65, depending on the dispersal of the adhesive 70.

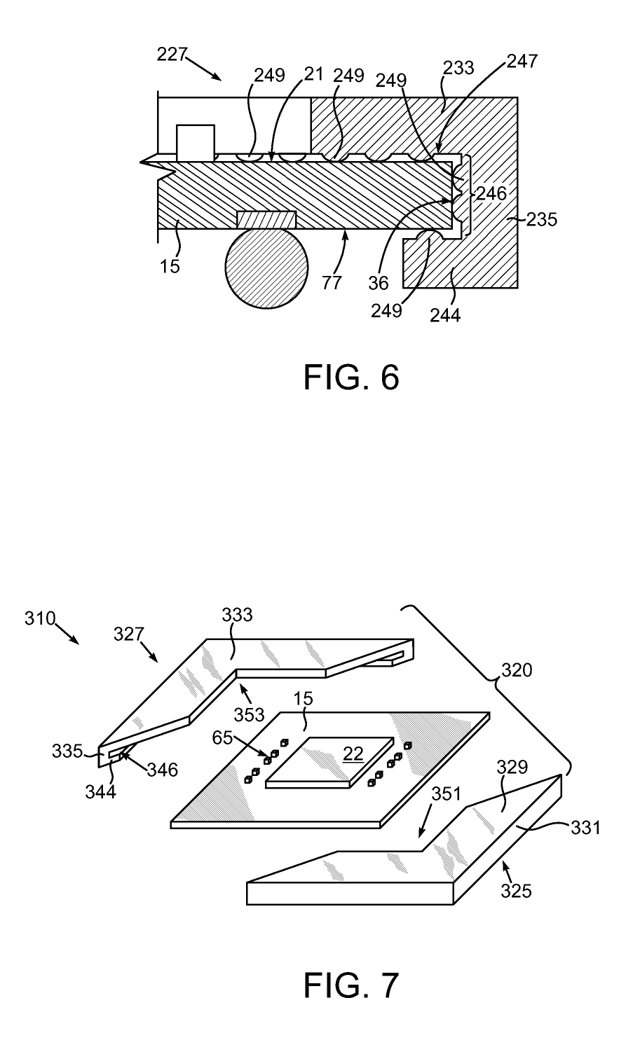

FIG. 6 is a sectional view like FIG. 5 but of an alternate exemplary embodiment of a ring portion 227. The ring portion 227 is similar in design and function to the ring portion 127 depicted in FIG. 5, and thus may include a flange 233 and an opposing flange 244 joined by a peripheral wall 235 to leave a slot 246. However, in lieu of using an adhesive to secure the ring portion 227 to the circuit board 15, a friction fit is utilized. In this regard, the flange 233, the peripheral wall 235 and the flange 244 may be provided with plural bumps 249, which are designed to engage external surfaces of the circuit board 15, such as the principal sides 21 and 77 and external peripheral wall 36. In this way, the ring portion 227 may be slipped over the circuit board 15 and held in place by way of friction between the bumps 249 and the circuit board 15. The number and spacing of the bumps 249 as well as the arrangement thereof may be selected to provide a requisite level of friction between the portion 227 and the circuit board 15. This arrangement eliminates the need for an adhesive while still providing significant structural engagement to limit the warpage of the circuit board 15, and may be used with any of the disclosed embodiments.

FIG. 7 is a partially exploded pictorial view of another exemplary embodiment of a semiconductor chip device 310 that includes the circuit board 15 and semiconductor chip 22 arrangement substantially as described above. In addition, an alternate exemplary stiffener ring 320 may include cooperating portions 325 and 327 that are configured as opposing elbow-shaped members as shown. Like the embodiment depicted in FIG. 4, the portions 325 and 327 include respective flanges 329 and 333 and peripheral walls 331 and 335. The ring portion 327 also includes a lower flange 344 and together the flange 333, the peripheral wall 335 and the flange 344 define a slot 346 to engage portions of the circuit board 15. The ring portion 325 includes the same slot structure that is not visible in FIG. 7. The portion 325 may include a triangular cut out 351 and the portion 327 may similarly include an opposing triangular cut out 353 that together with the triangular cut out 351 make up a generally rectangular or square opening to accommodate both the semiconductor chip 22 and the surface components 65. The portions 325 and 327 could be alternatively configured with downwardly projecting peripheral walls 331 and 335.

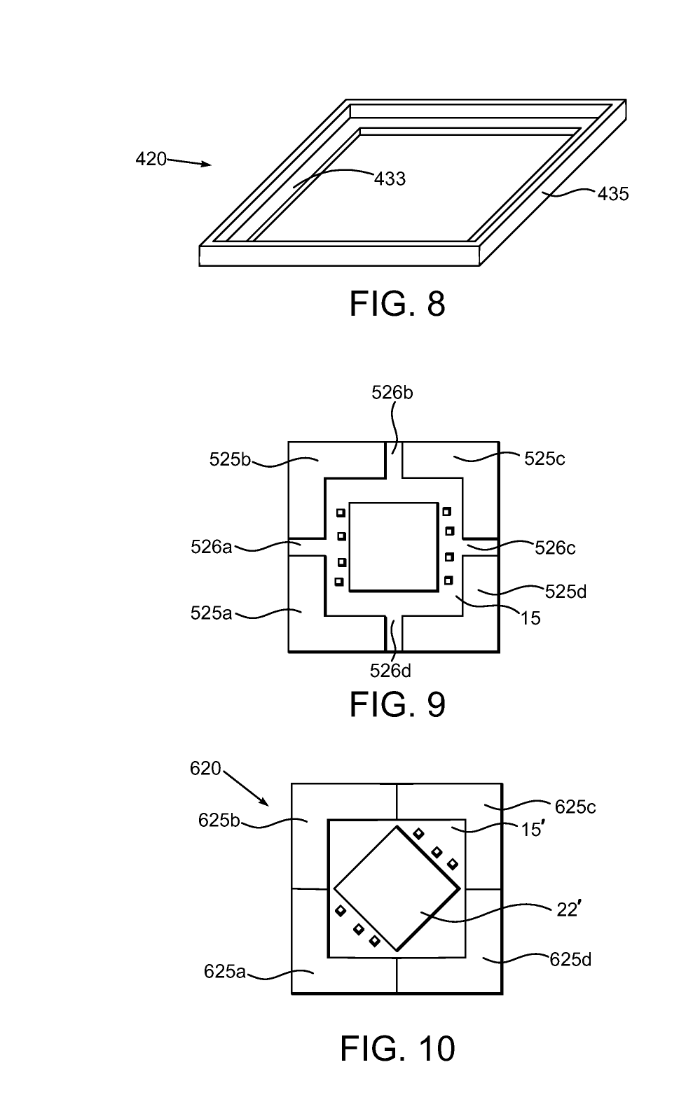

In the foregoing illustrative embodiments, the stiffener ring embodiments 20, 120, 320, etc. consist of two mating portions. However, the skilled artisan will appreciate that a unitary arrangement may be used as well. In this regard, attention is now turned to FIG. 8, which is a pictorial view of an alternate exemplary stiffener ring 420 that consists of a unitary frame member with a top flange 433 and a downwardly projecting flange 435. Note that the stiffener ring 420 is flipped over from the orientation of the ring 20 depicted in FIG. 1 for example. The stiffener ring 420 may be secured to the circuit board 15 depicted elsewhere herein using the aforementioned adhesive in contact with the peripheral wall 435 and/or the flange 433 and opposing surfaces of the circuit board 15 shown elsewhere.

The skilled artisan will appreciate that any of the illustrative embodiments of the stiffener ring disclosed herein may consist of other than one or two pieces. For example, and as shown in the plan view of FIG. 9, a stiffener ring 520 may consist of four elbow-shaped sections 525a, 525b, 525c and 525d. The sections 525a, 525b, 525c and 525d may be sized such that when mounted to the circuit board 15, gaps 526a, 526b, 526c and 526d remain. Optionally, the sections 525a, 525b, 525c and 525d may be sized so that each adjoins an adjacent section when mounted to the circuit board 15. It should be understood that the sections 525a, 525b, 525c and 525d may be configured like the stiffener ring 20 depicted in FIGS. 1 and 2 with a downwardly projecting peripheral wall but without a bottom flange. Optionally, the sections 525a, 525b, 525c and 525d may be configured with upper and lower flanges and a connecting peripheral wall such as depicted with regard to the embodiment shown in FIGS. 4 and 5.

FIG. 10 depicts a plan view of the stiffener ring 620 mounted to a circuit board 15′ with a semiconductor chip 22′ that is rotated relative to the circuit board 15′. In this illustrative embodiment, the ring 620 includes sections 625a, 625b, 625c and 625d that engage opposing surfaces and thus leave no gaps. FIG. 10 merely illustrates various additional possibilities with regard to the types of circuit board and semiconductor chip arrangements that may be strengthened by way of any of the disclosed embodiments of the stiffener rings 20, 120, 320 . . . 620, etc.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims. The terms “upper” and “lower” are used herein for ease of description and may not denote particular spatial positions.

What is claimed is:

1. A method of manufacturing, comprising:
fabricating a stiffener ring having a first flange to engage a first principal side of a circuit board and a peripheral wall to engage an external peripheral wall of the circuit board.

2. The method of claim 1, wherein the stiffener ring comprises a second flange coupled to the peripheral wall to engage a second principal side of the circuit board.

3. The method of claim 2, wherein the stiffener ring comprises plural bumps adapted to project toward and engage the circuit board.

4. The method of claim 1, wherein the stiffener ring comprises two portions, each of the portions being mountable on the circuit board.

5. The method of claim 4, wherein the two portions comprise elbow-shaped members.

6. The method of claim 1, wherein the stiffener ring comprises four portions, each of the portions being mountable on the circuit board.

7. The method of claim 1, wherein the circuit board comprises a semiconductor chip package substrate.

8. An apparatus, comprising:
a stiffener ring having a first flange to engage a first principal side of a circuit board and a peripheral wall to engage an external peripheral wall of the circuit board.

9. The apparatus of claim 8, wherein the stiffener ring comprises a second flange coupled to the peripheral wall to engage a second principal side of the circuit board.

10. The apparatus of claim 9, wherein the stiffener ring comprises plural bumps adapted to project toward and engage the circuit board.

11. The apparatus of claim 8, wherein the stiffener ring comprises two portions, each of the portions being mountable on the circuit board.

12. The apparatus of claim 11, wherein the two portions comprise elbow-shaped members.

13. The apparatus of claim 8, wherein the stiffener ring comprises four portions, each of the portions being mountable on the circuit board.

14. An apparatus, comprising:
a circuit board having a first principal side, a second principal side and external peripheral wall; and
a stiffener ring having a first flange to engage the first principal side and a peripheral wall to engage the external peripheral wall of the circuit board.

15. The apparatus of claim 14, wherein the stiffener ring comprises a second flange coupled to the peripheral wall to engage a second principal side of the circuit board.

16. The apparatus of claim 15, wherein the stiffener ring comprises plural bumps adapted to project toward and engage the circuit board.

17. The apparatus of claim 14, wherein the stiffener ring comprises two portions, each of the portions being mountable on the circuit board.

18. The apparatus of claim 17, wherein the two portions comprise elbow-shaped members.

19. The apparatus of claim 14, wherein the stiffener ring comprises four portions, each of the portions being mountable on the circuit board.

20. The apparatus of claim 14, wherein the circuit board comprises a semiconductor chip package substrate.
